(19) United States
(12) Patent Application Publication
(10) Pub. No.: US 2022/0005855 A1
(43) Pub. Date: Jan. 6, 2022

(54) SOLID-STATE IMAGING DEVICE

(71) Applicant: Panasonic Intellectual Property Management Co., Ltd., Osaka (JP)

(72) Inventors: Masaki TAMARU, Kyoto (JP); Shigetaka KASUGA, Osaka (JP); Yusuke SAKATA, Osaka (JP); Mitsuyoshi MORI, Kyoto (JP); Shinzo KOYAMA, Osaka (JP)

(21) Appl. No.: 17/479,846

(22) Filed: Sep. 20, 2021

Related U.S. Application Data
(63) Continuation of application No. PCT/JP2020/008981, filed on Mar. 3, 2020.

(30) Foreign Application Priority Data
Mar. 28, 2019 (JP) 2019-065097

(51) Int. Cl. H01L 27/146

(52) U.S. Cl. CPC H01L 27/14612; H01L 27/14636

(57) ABSTRACT

A plurality of pixel cells are provided on a semiconductor substrate and arranged in a two-dimensional array. At least one of the plurality of pixel cells includes a light receiving part, a pixel circuit, and a second transistor. The light receiving part receives an incident light to generate an electrical charge. The pixel circuit includes first transistors arranged side by side along a first direction and a charge retention part that retains the electrical charge generated by the light receiving part. The pixel circuit outputs a light receiving signal in accordance with the electrical charge generated by the light receiving part. The second transistor connects the charge retention part to a memory part that stores the electrical charge. Seen along a thickness direction of the semiconductor substrate, the second transistor is apart from the first transistors in a second direction orthogonal to the first direction.

### CROSS-REFERENCE TO RELATED APPLICATIONS

The present application is a Bypass continuation of International Application No. PCT/JP2020/008981, filed on Mar. 3, 2020, which is based upon and claims the benefit of priority to Japanese Patent Application No. 2019-065097, filed on Mar. 28, 2019, the entire contents of both applications are incorporated herein by reference.

### TECHNICAL FIELD

The present disclosure relates to solid-state imaging devices, and more particularly, to a solid-state imaging device including a plurality of pixel cells.

### BACKGROUND ART

JPH07-67043A (hereinafter, referred to as “Document 1”) discloses a solid-state imaging device. This solid-state imaging device includes: a light receiving element having a photoelectric conversion function; a reset means that repeatedly resets the light receiving element; and a detection means that detects information about whether there has been an incident photon during a period between reset pulses that reset the light receiving element. The solid-state imaging device further includes: a counter value holding means that counts the number of detection pulse of the detection means during a predetermined period; and a reading means that reads out the counted value of the counter value holding means every predetermined period.

### SUMMARY

The technical field of a solid-state imaging device such as the solid-state imaging device disclosed in Document 1 may desire to achieve high sensitivity and high integration of pixel cells that include the light receiving elements (light receiving parts), in some cases.

The present disclosure is directed to a solid-state imaging device for achieving high sensitivity and high integration.

A solid-state imaging devices of one aspect of the present disclosure includes a plurality of pixel cells formed on one surface of a semiconductor substrate. At least one pixel cell of the plurality of pixel cells includes a light receiving part, a pixel circuit, and a second transistor. The light receiving part is configured to receive an incident light to generate an electrical charge. The pixel circuit includes a plurality of first transistors arranged side by side along a first direction, and a charge retention part configured to retain the electrical charge generated by the light receiving part. The pixel circuit is configured to output a light receiving signal in accordance with the electrical charge generated by the light receiving part. The second transistor connects the charge retention part to a memory part configured to store the electrical charge. The at least one pixel cell is configured such that, in plan view seen along a thickness direction of the semiconductor substrate, the second transistor is apart from the plurality of first transistors in a second direction that is orthogonal to the first direction.

### BRIEF DESCRIPTION OF DRAWINGS

The figures depict one or more implementation in accordance with the present teaching, by way of example only, not by way of limitations. In the figures, like reference numerals refer to the same or similar elements, where:

FIG. 1 is an illustrative view illustrating an arrangement of a plurality of pixel cells of a solid-state imaging device according to an embodiment;

FIG. 2 is an illustrative view illustrating an arrangement of a light receiving part, first transistors, and a second transistor included in a pixel cell of the solid-state imaging device according to the embodiment;

FIG. 3 is a circuit diagram of the pixel cell according to the embodiment;

FIG. 4 is an illustrative view illustrating an arrangement of the plurality of pixel cells of the solid-state imaging device according to the embodiment;

FIG. 5 is a sectional view taken along a line V-V of FIG. 4, and illustrates the plurality of pixel cells of the solid-state imaging device according to the embodiment;

FIG. 6 is an illustrative view illustrating a connection between a first circuit and a second circuit in a pixel cell of a solid-state imaging device according to a variation;

FIG. 7 is an illustrative view illustrating an arrangement of a plurality of pixel cells of the solid-state imaging device according to the variation.

### DETAILED DESCRIPTION

A solid-state imaging device of an embodiment of the present disclosure will be explained with reference to drawings. However, the embodiment described below is mere an example of various embodiments of the present disclosure. The below described embodiment may be modified in various ways in accordance with design or the like as long as the object of the present disclosure can be achieved. Figures referred to in the following embodiment are schematic, and there is no guarantee that ratios regarding sizes and thicknesses of components shown in the figures reflect actual ratios.

### (1) Embodiment

### (1.1) Overview

A solid-state imaging device 1 of the present embodiment may be used in a distance measurement system that acquires a distance image of a target space based on the Time Of Flight (TOF) method, for example.

The distance measurement system includes, for example: a wave transmission module that outputs a pulsed light; a wave receiving module that receives the pulsed light (reflected light) output from the wave transmission module and reflected by an object; and a processor that determines a distance of the object based on the reflected light received by the wave receiving module. The processor can determine the distance of the object based on: a timing when the wave transmission module outputs the pulsed light; and a timing when the wave receiving module receives the reflected light.

The pulsed light output from the wave transmission module may be monochromatic, with a relatively short pulse width, and a relatively high peak intensity. In view of the use of the distance measurement system in an urban area, the wavelength of the pulsed light may be within the wavelength range of the near infrared band where the human visual sensitivity is low and insusceptible to the disturbance light from sunlight.

Such a distance measurement system may be employed in an object detection system installed on an automobile to detect an obstacle, a surveillance camera or security camera configured to detect an object (e.g., person), or the like, for example.

The solid-state imaging device 1 of the present embodiment may be used in the wave receiving module of the distance measurement system described above, for example.

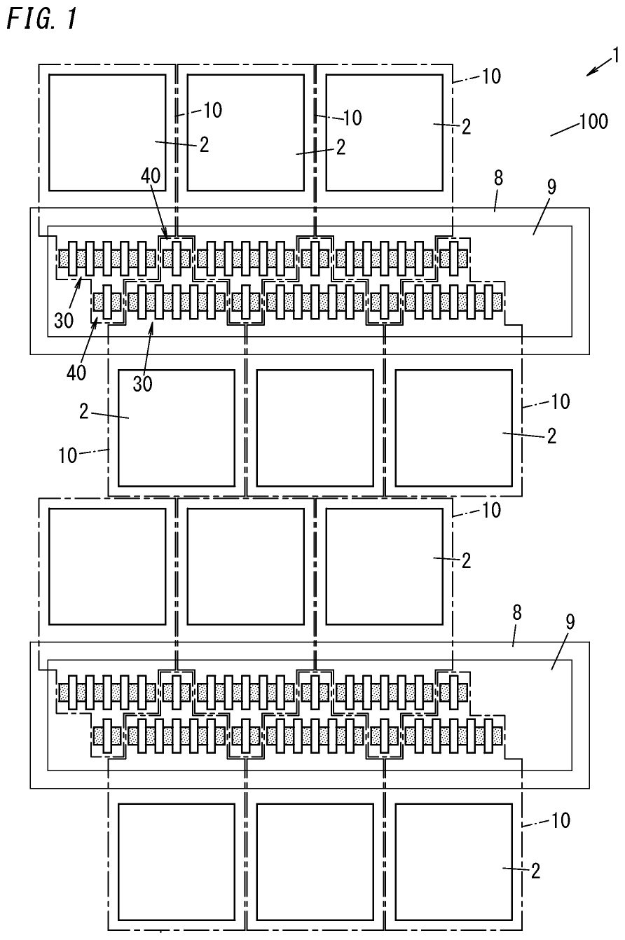

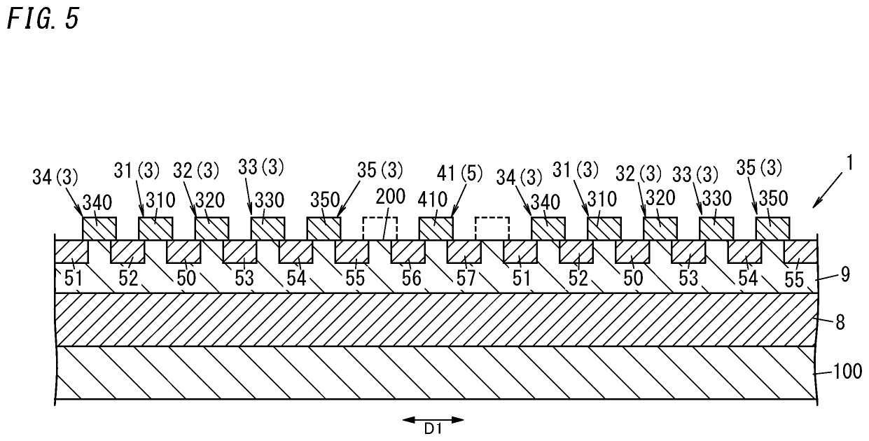

As shown in FIG. 1, the solid-state imaging device 1 includes a plurality of pixel cells 10. The plurality of pixel cells 10 are formed in a semiconductor substrate 100. The plurality of pixel cells 10 are formed in one surface 200 (see FIG. 5) in a thickness direction of the semiconductor substrate 100 and arranged in a two-dimensional array.

Specifically, according to the plurality of pixel cells 10, two or more pixel cells 10 are arranged side by side along one direction (right-left direction in FIG. 1) at equal intervals to form a pixel cell group, and two or more pixel cell groups are arranged side by side along another direction (upward-downward direction in FIG. 1) orthogonal to the one direction. With regard to two pixel cell groups adjacent to each other in the another direction, a pixel cell 10 of one pixel cell group is displaced in the one direction with respect to a pixel cell 10 of the other pixel cell group, by half a size of a pixel cell 10. That is, the plurality of pixel cells 10 are arranged in a so-called staggered arrangement. For convenience of description, in FIG. 1, illustration is omitted for a wiring 60 that connects a light receiving unit 2 and a first circuit 30, a wiring 61 that connects the first circuit 30 and a second circuit 40, and the like.

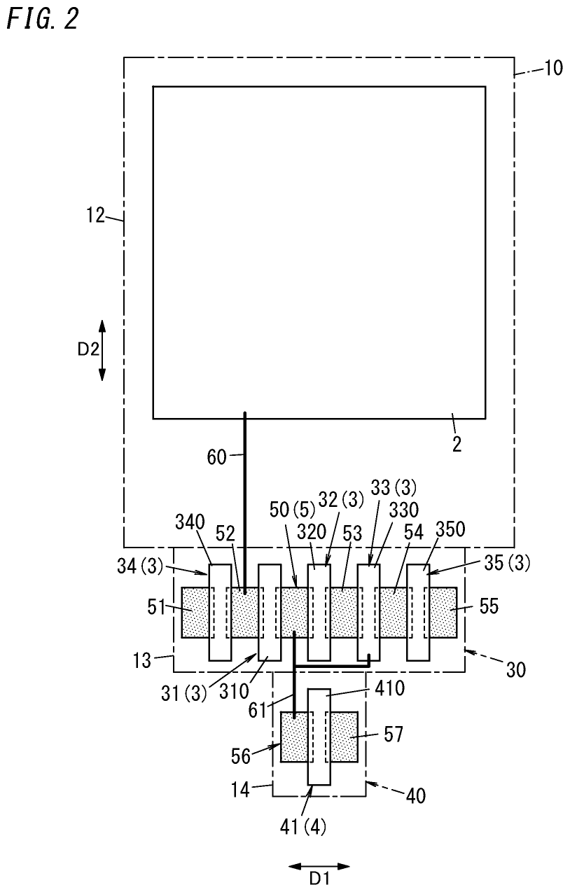

As shown FIG. 2, at least one pixel cell 10 of the plurality of pixel cells 10 (in the embodiment, each of the plurality of pixel cells 10) includes a light receiving part 2, a pixel circuit (hereinafter, also referred to as “first circuit”) 30, and a second circuit 40.

The light receiving part 2 is formed in the semiconductor substrate 100. The light receiving part 2 functions as a photoelectric converter that receives an incident light to generate an electrical charge. The light receiving part 2 is formed in a first region 12 of the pixel cell 10.

The first circuit (pixel circuit) 30 includes a circuit configured to output a light receiving signal in accordance with the electrical charge generated by the light receiving part 2. The first circuit 30 is formed in a second region 13 of the pixel cell 10, which is different from the first region 12.

The first circuit 30 includes a plurality of first transistors 3. The plurality of first transistors 3 is formed in the semiconductor substrate 100. The plurality of first transistors 3 (specifically, respective gate electrodes of the plurality of first transistors 3) are arranged side by side along a first direction D1 that is orthogonal to the thickness direction of the semiconductor substrate 100.

The first circuit 30 includes a charge retention part 5. The charge retention part 5 is connected to the light receiving part 2 by a wiring 60 via a first transistor 3 (transfer transistor 31 described later). The charge retention part 5 is configured to retain (store) the electrical charge generated by the light receiving part 2.

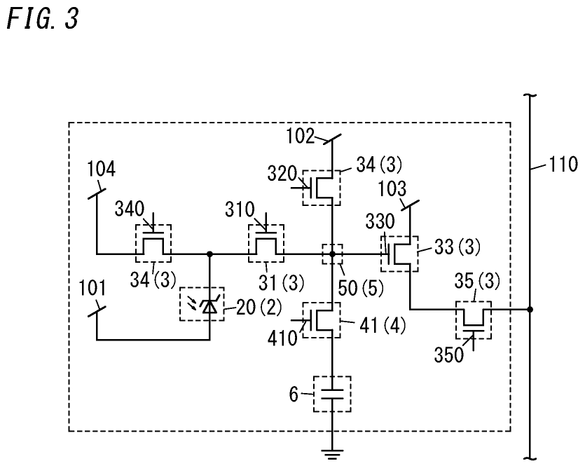

The second circuit 40 is formed in a third region 14 of the pixel cell 10, which is different from the first region 12 and second region 13. The second circuit 40 includes a second transistor 4. The second transistor 4 is formed in the semiconductor substrate 100. The second transistor 4 connects the charge retention part 5 of the first circuit 30 to a memory part 6 (see FIG. 3) configured to store the electrical charge. The second transistor 4 is connected to the charge retention part 5 by a wiring 61.

As shown in FIG. 2, the second transistor 4 is apart from the plurality of first transistors 3 in a second direction D2 that is orthogonal to each of the first direction D1 and the thickness direction of the semiconductor substrate 100. In other words, at least one pixel cell 10 of the plurality of pixel cells 10 (in the embodiment, each of the plurality of pixel cells 10) is configured such that, in plan view seen along the thickness direction of the semiconductor substrate 100 (seen in a normal direction of a sheet of FIG. 2), the second transistor 4 is apart from the plurality of first transistors 3 in the second direction D2 that is orthogonal to the first direction D1 along which the plurality of first transistors 3 are arranged side by side. In the embodiment, the second transistor 4 is placed alongside of a first transistor 3 in the second direction D2.

The solid-state imaging device 1 of the present embodiment can reduce a length of the wiring 61 that connects the second transistor 4 and the charge retention part 5 together, compared to a pixel cell 10 where a second transistor 4 is not apart from a plurality of first transistors 3 in a second direction D2, namely where a second transistor 4 is placed alongside of a plurality of first transistors 3 in a first direction D1. This can reduce the parasitic capacitance of the wiring 61 to achieve high gain for the photoelectric conversion and high sensitivity. This also can reduce the parasitic resistance of the wiring 61 to achieve a high responsiveness for the transfer of electrical charge. Furthermore, pixel cells 10 can be arranged adjacent to each other such that the first circuit 30 of one and the second circuit 40 of the other are disposed in proximity, which can achieve high integration of the pixel cells.

### (1.2) Details

The solid-state imaging device 1 of the present embodiment will be explained in more detail with reference to FIG. 1 to FIG. 5.

As shown in FIG. 1, the solid-state imaging device 1 includes the semiconductor substrate 100. The plurality of pixel cells 10 are formed in the semiconductor substrate 100. That is, the solid-state imaging device 1 includes the plurality of pixel cells 10. The plurality of pixel cells 10 are formed in the semiconductor substrate 100 and arranged in a two-dimensional array.

### (1.2.1) Circuit Configuration of Pixel Cell

The circuit configuration of the pixel cell 10 is explained with reference to FIG. 3.

As shown in FIG. 3, the pixel cell 10 includes the light receiving part 2, the plurality of first transistors 3, the second transistor 4, the charge retention part 5, and the memory part 6. The plurality of first transistors 3 and the charge retention part 5 are included in the first circuit 30. The second transistor 4 is included in the second circuit 40.

The light receiving part 2 includes a photodiode formed in a surface region of the semiconductor substrate 100 closer to the one surface 200. The photodiode may be an avalanche photodiode (hereinafter, also referred to as “APD”) 20. The APD 20 includes an n-type diffusion region formed in the p-type semiconductor substrate 100.

The APD 20 includes, as its operation mode, a first mode and a second mode. While being applied a reverse biased voltage smaller than its breakdown voltage, the APD 20 collects, in response to a received light, into the cathode an electrical charge substantially proportional to the number of photons causing the photoelectric conversion (operating in the first mode). While being applied a reverse biased voltage equal to or greater than the breakdown voltage, the APD 20 collects, in response to reception of light of a single photon, into the cathode an amount of electrical charge corresponding to a saturation level by the photoelectrical conversion (operating in the second mode). The operation mode of the APD 20 can be changed by changing the potential of a bias electrode 101 connected to the anode.

The charge retention part 5 is configured to retain the electrical charge generated by the light receiving part 2. A diffusion region 50 (hereinafter, also referred to as “first diffusion region”) is so-called a floating diffusion (FD).

The plurality of first transistors 3 includes a transfer transistor 31, a first reset transistor 32, and an amplifier transistor 33. In the present embodiment, the plurality of first transistors 3 further includes a second reset transistor 34 and a select transistor 35.

The transfer transistor 31 includes two impurity diffusion regions formed in the semiconductor substrate 100, and a gate electrode 310. One of the impurity diffusion regions of the transfer transistor 31 is connected to the cathode of the APD 20, and the other thereof is connected to the diffusion region (first diffusion region) 50.

When being turned on with a voltage applied to the gate electrode 310, the transfer transistor 31 moves (transfers) the electrical charge collected in the cathode of the APD 20 to the first diffusion region 50.

The first reset transistor 32 includes two impurity diffusion regions formed in the semiconductor substrate 100, and a gate electrode 320. One of the impurity diffusion regions of the first reset transistor 32 is connected to a first reset drain electrode 102. The other of impurity diffusion regions of the first reset transistor 32 is connected to the diffusion region (first diffusion region) 50.

When being turned on with a voltage applied to the gate electrode 320, the first reset transistor 32 causes the first diffusion region 50 to discharge the stored electrical charge to the first reset drain electrode 102 (namely, resets the first diffusion region 50).

The amplifier transistor 33 includes two impurity diffusion regions formed in the semiconductor substrate 100, and a gate electrode 330. One of the impurity diffusion regions of the amplifier transistor 33 is connected to an amplifier electrode 103, and the other thereof is connected to a signal line 110 via the select transistor 35. The gate electrode 330 of the amplifier transistor 33 is connected to the first diffusion region 50.

The amplifier transistor 33 outputs a voltage indicative of the amount of electrical charge stored in the first diffusion region 50. The output voltage of the amplifier transistor 33 serves as a light receiving signal output from the pixel cell 10 (namely, a light receiving signal in accordance with the electrical charge generated by the light receiving part 2).

The select transistor 35 includes two impurity diffusion regions formed in the semiconductor substrate 100, and a gate electrode 350. One of the impurity diffusion regions of the select transistor 35 is connected to the impurity diffusion region of the amplifier transistor 33, and the other thereof is connected to the signal line 110.

Only when being turned on with a voltage applicated to the gate electrode 350, the select transistor 35 allows the voltage of the amplifier transistor 33 (namely, the light receiving signal) to be output to the signal line 110.

The second reset transistor 34 includes two impurity diffusion regions formed in the semiconductor substrate 100, and a gate electrode 340. One of the impurity diffusion regions of the second reset transistor 34 is connected to a second reset drain electrode 104. The other of the impurity diffusion regions of the second reset transistor 34 is connected to the cathode of the APD 20.

When being turned on with a voltage applied to the gate electrode 340, the second reset transistor 34 causes the cathode of the APD 20 to discharge the stored electrical charge to the second reset drain electrode 104 (namely, resets the cathode of the APD 20).

The memory part 6 may include a capacitor that stores an electrical charge. The memory part 6 have a stacked structure including a pair of electrodes and an insulation layer sandwiched therebetween. Alternatively, the memory part 6 may have a stacked structure including an electrode, a semiconductor layer, and an insulation layer sandwiched therebetween. The memory part 6 is disposed on the one surface 200 of the semiconductor substrate 100 via an insulation layer, for example.

The second transistor 4 (hereinafter, also referred to as “counter transistor 41”) includes two impurity diffusion regions formed in the semiconductor substrate 100, and a gate electrode 410.

The counter transistor 41 is connected between the first diffusion region 50 and the memory part 6. One of the impurity diffusion regions of the counter transistor 41 is connected to the first diffusion region 50, and the other thereof is connected to the memory part 6.

When being turned off with no voltage applied to the gate electrode 410, the counter transistor 41 forbids the transfer of electrical charge between the first diffusion region 50 and the memory part 6. When being turned on with a voltage applied to the gate electrode 410, the counter transistor 41 allows the transfer of the electrical charge between the first diffusion region 50 and the memory part 6.

### (1.2.2) Operation

It will be explained about the light receiving operation of the solid-state imaging device 1. The solid-state imaging device 1 includes a controller (control circuit) that controls the operation of the pixel cell 10. The controller controls the operation of the pixel cell 10 by controlling the voltage applied to the bias electrode 101, the respective voltages applied to the gate electrodes of the first transistors 3, and the voltage applied to the gate electrode of the second transistor 4 of the pixel cell 10.

The controller of the solid-state imaging device 1 includes, as its operation mode, a first receiving mode and a second receiving mode. While operating in the first receiving mode, the controller controls the APDs 20 of the pixel cells 10 to operate in the first mode (i.e., adjusts the voltages applied to the bias electrodes 101 so that the APDs 20 operate in the first mode). While operating in the second receiving mode, the solid-state imaging device 1 controls the APDs 20 of the pixel cells 10 to operate in the second mode (i.e., adjusts the voltages applied to the bias electrodes 101 so that the APDs 20 operate in the second mode). The second receiving mode is suitable for detecting a weak light, compared to the first receiving mode.

The solid-state imaging device 1 operates as in the following manner in the first receiving mode.

Firstly, the controller of the solid-state imaging device 1 turns on the first reset transistor 32, the second reset transistor 34, and the counter transistor 41 to reset (discharge the stored electrical charge of) the cathode of the APD 20, the charge retention part 5 (the first diffusion region 50) and the memory part 6, while keeping the transfer transistor 31 turned off

Next, the controller turns off the first reset transistor 32, the second reset transistor 34, and the counter transistor 41. This state is referred to as an exposure state of the pixel cell 10. The APD 20 in the exposure state collects, in response to the light received, into the cathode the electrical charge substantially proportional to the number of photons causing the photoelectric conversion.

It is noted that the second reset transistor 34 has an off-level potential lower than an off-level potential of the transfer transistor 31. Thus, when the amount of electrical charge collected into the cathode of the APD 20 reaches the saturation level of the cathode, the excess amount of electrical charge flows over the potential barrier of the second reset transistor 34 to overflow to the second reset drain electrode 104.

Then, the controller turns on the first reset transistor 32 to reset the charge retention part 5. The controller turns off the first reset transistor 32. The controller then turns on the transfer transistor 31 to connect the cathode of the APD 20 to the charge retention part 5. As a result, the electrical charge collected in the APD 20 is transferred to the charge retention part 5 (the first diffusion region 50) and stored therein.

The electrical charge stored in the charge retention part 5 is converted, by the amplifier transistor 33 whose gate electrode 330 is connected to the charge retention part 5, into the light receiving signal indicative of the amount of stored electrical charge.

The controller of the solid-state imaging device 1 turns on the select transistor 35 of a target pixel cell 10 to allow this pixel cell 10 to output the light receiving signal to the signal line 110.

The solid-state imaging device 1 operates as in the following manner in the second receiving mode. Specifically, the controller in the second receiving mode divides a predetermined measurement period so that it includes a plurality of exposure periods. The controller determines whether a photoelectric conversion phenomenon occurs in each of the exposure periods, corresponding respectively to exposure processes, thereby counting the number of photons that reach the light receiving part 2 during the measurement period.

Specifically, the controller of the solid-state imaging device 1 in the second receiving mode causes the pixel cell 10 to operate as in the following manner.

At the start point of the measurement period, the controller of the solid-state imaging device 1 turns on the first reset transistor 32, the second reset transistor 34, and the counter transistor 41 to reset the cathode of the APD 20, the charge retention part 5 (the first diffusion region 50) and the memory part 6, while keeping the transfer transistor 31 turned off

At a start point of each of the exposure processes of the exposure periods, the controller turns off the first reset transistor 32, the second reset transistor 34, and the counter transistor 41. This state is the exposure state of the pixel cell 10. When receiving light in the exposure state, the APD 20 collects into the cathode the amount of electrical charge corresponding to the saturation level by the photoelectric conversion, in response to a single photon. As noted above, the off-level potential of the second reset transistor 34 is lower than the off-level potential of the transfer transistor 31. Thus, the collected electrical charge excessed above the saturation level of the cathode of the APD 20 flows over the potential barrier of the second reset transistor 34 to overflow to the second reset drain electrode 104. This means that the amount of electrical charge stored in the cathode of the APD 20 in the second mode (corresponding to the amount of electrical charge to be stored in the cathode in response to the photoelectric conversion elect caused by a single photon) may be substantially the same (at the amount of electrical charge corresponding to the saturation level of the cathode) every time.

Next, the controller turns on the transfer transistor 31 to connect the cathode of the APD 20 to the charge retention part 5 (the first diffusion region 50). As a result, the electrical charge collected in the APD 20 is distributed to the cathode of the APD 20 and the charge retention part 5 (the first diffusion region 50).

The controller then turns off the transfer transistor 31. As a result, a part, distributed to the charge retention part 5, of the electrical charge collected in the cathode of the APD 20 will be retained in the charge retention part 5.

The controller turns on the counter transistor 41 to re-distribute the electrical charge stored in the charge retention part 5 to the charge retention part 5 and the memory part 6. This means that the controller transfers, to the memory part 6, (part of) the electrical charge stored in the charge retention part 5. Therefore, part of the electrical charge generated with the photoelectric conversion by the light receiving part 2 is transferred to the memory part 6 to increase the stored amount of electrical charge in the memory part 6.

On the other hand, when the APD 20 receives no light during the exposure period, the photoelectric conversion effect does not occur and the APD 20 does not collect the electrical charge in the cathode. Thus, no electrical charge is transferred from the cathode of the APD 20 to the charge retention part 5 when the controller turns on the transfer transistor 31. This means that the amount of electrical charge in the memory part 6 does not increase when the counter transistor 41 is turned on thereafter.

The controller repeats the above operation by the number of times of the exposure process. As a result, the memory part 6 stores such amount of electrical charge that corresponds to the number of times of exposure process during which the APD 20 receives light, out of the plurality of exposure processes contained in one measurement period.

It may be noted that, in a case where the APD 20 receives the light at the first exposure process, some amount of electrical charge is already stored in the memory part 6 before the second or later exposure process. This means that the amount of increase of the electrical charge of the memory part 6 for the second or later exposure process may be different from the amount of increase of the electrical charge for the first exposure process. It may also be noted that the first reset transistor 32 is not necessarily turned off at the start point of the second or later exposure process. However, these points are not explained further in detail since they are not the purpose of the present disclosure.

At the end of the measurement period (i.e, all of the plurality of exposure processes are finished), the controller turns on the counter transistor 41 to connect the memory part 6 to the charge retention part 5, thereby distributing the electrical charge stored in the memory part 6 to the memory part 6 and the charge retention part 5. The electrical charge distributed from the memory part 6 to the charge retention part 5 is converted, by the amplifier transistor 33 whose gate electrode 330 is connected to the charge retention part 5, into the light receiving signal indicative of the amount of electrical charge (i.e., indicative of the number of times of the exposure process during which the APD 20 receives light).

The controller of the solid-state imaging device 1 turns on the select transistor 35 of a target pixel cell 10 to allow this pixel cell 10 to output the light receiving signal to the signal line 110.

### (1.2.3) Arrangement

It will be described a layout of the plurality of pixel cells 10 in the solid-state imaging device 1 and a layout of the pixel cell 10 of the present embodiment with reference to FIGS. 1, 2, 4, and 5.

As shown in FIG. 1, the plurality of pixel cells 10 are formed in the semiconductor substrate 100 in a two-dimensional array.

The semiconductor substrate 100 may be a p-type silicon substrate. The semiconductor substrate 100 has the one surface 200 (one surface in the thickness direction) formed therein with a n-type well region 8 extending in one direction (right-left direction in FIG. 1). A p-type well region 9 is formed in the n-type well region 8 to extend along a longitudinal direction of the n-type well region 8.

In each of the pixel cells 10, the first circuit 30 and the second circuit 40 are formed in the p-type well region 9. In each of the pixel cells 10, the light receiving part 2 is formed at a location in a p-type region that is formed on an outside of the n-type well region 8 and in the semiconductor substrate 100.

Two or more (three in the example of FIG. 1) pixel cells 10 (hereinafter, referred to as “first pixel cell group”) are arranged side by side along one of the long sides of one p-type well region 9. Along the other of the long sides of this p-type well region 9, another two or more (three in the example of FIG. 1) pixel cells 10 (hereinafter, referred to as “second pixel cell group”) are arranged side by side. Inside this p-type well region 9 are formed first circuits 30 and second circuits 40 of respective pixel cells 10 of the first pixel cell group, and first circuits 30 and second circuits 40 of respective pixel cells 10 of the second pixel cell group. In the example of FIG. 1, the first circuits 30 and the second circuits 40 of total six pixel cells 10 of the first and second pixel cell groups are formed in this one p-type well region 9, but is not limited thereto. Alternatively, the first pixel cell group may include one, two, four or more pixel cell(s) 10, and/or the second pixel cell group may include one, two, four or more pixel cell(s) 10. The number of pixel cells 10 of the second pixel cell group may be the same as or different from the number of pixel cells 10 of the first pixel cell group.

As shown in FIG. 1, the plurality of pixel cells 10 have the same shape as each other in plan view seen along the thickness direction of the semiconductor substrate 100 (seen in a normal direction of a sheet of FIG. 1). In the example of FIG. 1, the plurality of pixel cells 10 of the first pixel cell group have the same shape as each other. The plurality of pixel cells 10 of the second pixel cell group have the same shape as each other. Moreover, the pixel cell 10 of the first pixel group and the pixel cell 10 of the second pixel cell group have the same shape as each other. Such a configuration that the plurality of pixel cells 10 have the same shape as each other enables the wirings 60, 61 of the plurality of pixel cells 10 to have substantially the same shape. This can equalize the length of the wirings 60, 61 of the plurality of pixel cells 10 to equalize the parasitic resistance and parasitic capacitance of the wirings 60, 61. This further can reduce the piece-to-piece variation in the characteristics of the pixel cell 10.

The plurality of pixel cells 10 includes two pixel cells adjacent in the second direction D2 (in the width direction of the p-type well; upward-downward direction in FIG. 1). In plan view seen along the thickness direction of the semiconductor substrate 100, the light receiving part 2 of one of the two pixel cells 10 is adjacent to the light receiving part 2 of the other of the two pixel cells 10, or the first circuit (pixel circuit) 30 one of the two pixel cells 10 is adjacent to the first circuit (pixel circuit) 30 of the other of the two pixel cells 10.

As shown in FIG. 2, the light receiving part 2 is formed in the first region 12, the first circuit 30 is formed in the second region 13, and the second circuit 40 is formed in the third region 14. The first region 12, the second region 13, and the third region 14 are arranged in this order along the second direction D2.

As shown in FIGS. 2, 4, and 5, the first circuit 30 of each pixel cell 10 includes: a plurality of (six, in the embodiment) diffusion regions 50 to 55 arranged side by side along the first direction D1; and a plurality of gate electrodes 310 to 350 arranged side by side along the first direction D1.

Each of the plurality of diffusion regions 50 to 55 is a n-type diffusion region formed in the p-type well region 9. As shown in FIG. 2, the diffusion regions 51, 52, 50, 53, 54, and 55 are arranged in this order along the first direction D1.

Each of the plurality of gate electrodes 310 to 350 extends along the second direction D2 orthogonal to the first direction D1 and the thickness direction of the semiconductor substrate 100. The plurality of gate electrodes 310 to 350 have the same width (dimension in the first direction D1) and have the same length (dimension in the second direction D2). The gate electrodes 340, 310, 320, 330, and 350 are arranged in this order along the first direction D1.

Each of the plurality of gate electrodes 310 to 350 is formed on the one surface 200 of the semiconductor substrate 100 via a gate insulation film (not shown) made of silicon oxide and the like. Each of the plurality of gate electrodes 310 to 350 is formed on the one surface 200 of the semiconductor substrate 100 so as to bridge the ends of two diffusion regions adjacent in the first direction D1. These adjacent two diffusion regions together with the gate electrode bridging them and the gate insulation films constitute a first transistor 3. As such, the plurality of first transistors 3 are arranged side by side along the first direction D1.

Specifically, the plurality of first transistors 3 includes the second reset transistor 34, the transfer transistor 31, the first reset transistor 32, the amplifier transistor 33, and the select transistor 35.

The second reset transistor 34 includes the gate electrode 340, and the diffusion regions 51, 52. That is, the diffusion regions 51, 52 serve as the two impurity diffusion regions of the second reset transistor 34.

The transfer transistor 31 includes the gate electrode 310, and the diffusion regions 52. 50. That is, the diffusion region 52 serves as one of the impurity diffusion regions of the transfer transistor 31, and doubles as the impurity diffusion region of the second reset transistor 34. The diffusion region (first diffusion region) 50 serves as the other one of the impurity diffusion regions of the transfer transistor 31

The first reset transistor 32 includes the gate electrode 320, and the diffusion regions 50, 53. That is, the diffusion region 53 serves as one the impurity diffusion regions of the first reset transistor 32. The diffusion region (first diffusion region) 50 serves as the other one of the impurity diffusion regions of the first reset transistor 32, and doubles as the impurity diffusion region of the transfer transistor 31.

The amplifier transistor 33 includes the gate electrode 330, and the diffusion regions 53, 54. That is, the diffusion region 53 serves as one of the impurity diffusion regions of the amplifier transistor 33, and doubles as the impurity diffusion region of the first reset transistor 32. The diffusion region 54 serves as the other one of the impurity diffusion regions of the amplifier transistor 33.

The select transistor 35 includes the gate electrode 350, and the diffusion regions 54, 55. That is, the diffusion region 54 serves as one of the impurity diffusion regions of the select transistor 35, and doubles as the impurity diffusion region of the amplifier transistor 33. The diffusion region 55 serves as the other one of the impurity diffusion regions of the select transistor 35.

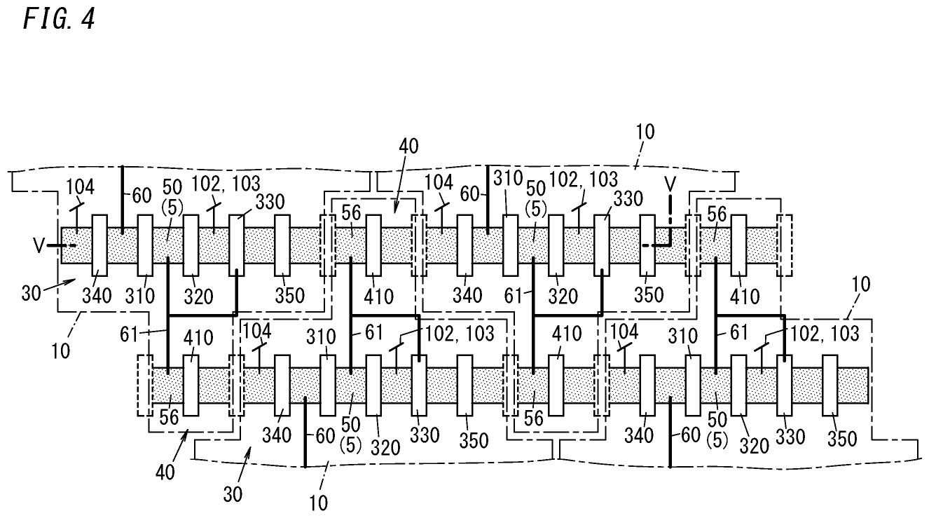

The plurality of gate electrodes 310 to 350 are arranged along and equally spaced in the first direction D1. Specifically, the gate electrode 340 of the second reset transistor 34, the gate electrode 310 of the transfer transistor 31, the gate electrode 320 of the first reset transistor 32, the gate electrode 330 of the amplifier transistor 33, and the gate electrode 350 of the select transistor 35 are arranged along and equally spaced in the first direction D1 (see FIGS. 4, and 5).

In other words, the gate electrodes of the plurality of first transistors 3 are arranged side by side along the first direction D1. Furthermore, two first transistors 3 of the plurality of first transistors 3 are positioned at both ends in the first direction D1, and gate electrodes of remaining first transistors 3 of the plurality of first transistors 3 are positioned at any of virtual points that equally divides a line segment connecting two gate electrodes (gate electrodes 340,350) of the two first transistors 3 positioned at both ends in the first direction D1.

As shown in FIG. 4, the diffusion region 51 (the impurity diffusion region of the second reset transistor 34) is connected to the second reset drain electrode 104. The diffusion region 53 (the impurity diffusion region of the first reset transistor 32 and the impurity diffusion region of the amplifier transistor 33) is connected to the first reset drain electrode 102 and the amplifier electrode 103.

The first reset drain electrode 102 and the amplifier electrode 103 may be shared with each other. The second reset drain electrode 104 may be shared with at least one of the first reset drain electrode 102 and the amplifier electrode 103. In the present embodiment, the first reset drain electrode 102, the amplifier electrode 103 and the second reset drain electrode 104 are shared with (connected to) each other, and are to be connected to a common power source.

The diffusion region 52 is connected to the light receiving part 2 by the wiring 60. The wiring 60 is a metal wiring, for example. The gate electrode 330 of the amplifier transistor 33 is connected to the first diffusion region 50 by the wiring 61. The wiring 61 is a metal wiring, for example.

As shown in FIGS. 2, 4, and 5, the second transistor 4 of the second circuit 40 of each pixel cell 10 includes two diffusion regions 56, 57 arranged along the first direction D1, and the gate electrode 410. That is, the diffusion region 56 serves as one of the impurity diffusion regions of the second transistor 4, and the diffusion region 57 serves as the other one thereof.

Each of the two diffusion regions 56, 57 is a n-type diffusion region formed in the p-type well region 9. The two diffusion regions 56, 57 of the second circuit 40 are arranged along a direction parallel to a direction (first direction D1) along which the plurality of diffusion regions 50 to 55 of the first circuit 30 are arranged side by side.

The gate electrode 410 has a width (dimension in the first direction D1) same as the width of each of the plurality of gate electrodes 310 to 350, and has a length (dimension in the second direction D2) same as the length of each of the plurality of gate electrodes 310 to 350. The gate electrode 410 is formed on the one surface 200 of the semiconductor substrate 100 via a gate insulation film (not shown) made of silicon oxide and the like. The gate electrode 410 is formed on the one surface 200 of the semiconductor substrate 100 so as to bridge the ends of the two diffusion regions 56, 57. The two diffusion regions 56, 57 together with the gate electrode 410 bridging them and the gate insulation films constitute the second transistor 4 (the counter transistor 41).

One diffusion region (hereinafter, referred to as “second diffusion region”) 56 of the diffusion regions of the second transistor 4 of the second circuit 40 is connected to the diffusion region (first diffusion region) 50 (the charge retention part 5) of the first circuit 30 by the wiring 61. That is, the second transistor 4 (the counter transistor 41) includes the diffusion region (second diffusion region) 56 connected to the first diffusion region 50. The second diffusion region 56 is a floating diffusion. The second diffusion region 56 has a potential floating with respect to the semiconductor substrate 100. The second diffusion region 56 is connected to the first diffusion region 50 by the wiring 61 (e.g., metal wiring).

As shown in FIG. 4, at least part of the diffusion region (the second diffusion region) 56 overlaps at least part of the first diffusion region 50 of the first circuit 30 when seen along the second direction D2 orthogonal to the first direction D1 along which the plurality of first transistors 3 are arranged side by side. Specifically, the first diffusion region 50 has the width (dimension in the first direction D1) same as the width of the second diffusion region 56. Moreover, when seen along the second direction D2: a whole of one of the first diffusion region 50 and the second diffusion region 56 overlaps the other of the second diffusion region 56 and the first diffusion region 50.

As such, in the pixel cell 10, a part (i.e., the first diffusion region 50), connected to the second circuit 40, of the first circuit 30 and a part (i.e., the second diffusion region 56), connected to the first circuit 30, of the second circuit 40 face each other in the second direction D2. This can reduce the length of the wiring 61 that connects the first circuit 30 and the second circuit 40. Moreover, this can increase the width (dimension in the first direction D1) of a connection portion of the wiring 60 connected to the first and second circuits 30, 40, which can decrease the resistance of the wiring 61.

As shown in FIG. 4, in adjacent (in the upward-downward direction in FIG. 4) two pixel cells 10 (hereinafter, referred to as a “first pixel cell” and a “second pixel cell”), the gate electrodes of the plurality of first transistors 3 of the first pixel cell and the gate electrode of the second transistor 4 of the second pixel cell are arranged side by side along the first direction D1 (see the arrangement of the gate electrodes 340, 310, 320, 330, 350, and 410 shown in FIG. 4). The gate electrodes of the plurality of first transistors 3 of the first pixel cell and the gate electrode of the second transistor 4 of the second pixel cell includes: two gate electrodes (gate electrodes 340, 410) of transistors positioned at both ends in the first direction D1; and gate electrodes of remaining transistors. The gate electrodes of the remaining transistors are positioned at any of virtual points that equally divides a line segment connecting the two gate electrodes of the transistors positioned at both ends in the first direction D1. With this arrangement, the first pixel cell and the second pixel cell can be formed such that the diffusion regions 50 to 55 of the first circuit 30 of the first pixel cell and the diffusion regions 56, 57 of the second circuit 40 of the second pixel cell are arranged side by side along the first direction D1. Moreover, the gate electrodes of the plurality of first transistors 3 of the first pixel cell and the gate electrode of the second transistor 4 of the second pixel cell can be arranged side by side along the first direction D1.

Moreover, in the example shown in FIG. 4, the gate electrodes of the plurality of first transistors 3 of the second pixel cell and the gate electrode of the second transistor 4 of the first pixel cell are arranged side by side along the first direction D1. The gate electrodes of the plurality of first transistors 3 of the second pixel cell and the gate electrode of the second transistor 4 of the first pixel include: two gate electrodes (gate electrodes 340, 410), of transistors positioned at both ends in the first direction D1; and gate electrodes of remaining transistors. The gate electrodes of the remaining transistors are positioned at any of virtual points that equally divides a line segment connecting the two gate electrodes of the transistors positioned at both ends in the first direction D1. With this arrangement, the first pixel cell and the second pixel cell can be formed such that the diffusion regions 50 to 55 of the first circuit 30 of the second pixel cell and the diffusion regions 56, 57 of the second circuit 40 of the first pixel cell are arranged side by side along the first direction D1. Moreover, the gate electrodes of the plurality of first transistors 3 of the second pixel cell and the gate electrode of the second transistor 4 of the first pixel cell can be arranged side by side along the first direction D1. This can arrange the first circuit 30 and the second circuit 40 of the first pixel cell and the second circuit 40 and the first circuit 30 of the second pixel cell in proximity, and can arrange the first circuit 30 and the second circuit 40 of the first pixel cell and the first circuit 30 and the second circuit 40 of the second pixel cell in a small area.

In the embodiment, the gate electrodes 310 to 350 of the plurality of first transistors 3 of the first pixel cell are arranged along the first direction D1 at equal intervals. When defining a length of an interval between centers of gate electrodes of first transistors 3 adjacent in the first direction D1 as “A1”, a length in the first direction D1 of an interval between a center of the gate electrode 410 of the second transistor 4 of the second pixel cell and a center of a gate electrode (340 or 350), adjacent thereto in the first direction D1, of a first transistor 3 of the first pixel cell is the twice the above length “A1” of the interval (i.e., 2*A1).

Furthermore, the gate electrodes 310 to 350 of the plurality of first transistors 3 of the second pixel cell are arranged along the first direction D1 at equal intervals. When defining a length of an interval between centers of gate electrodes of first transistors 3 adjacent in the first direction D1 as “A2”, a length in the first direction D1 of an interval between a center of the gate electrode 410 of the second transistor 4 of the first pixel cell and a center of a gate electrode (340 or 350), adjacent thereto in the first direction D1, of a first transistor 3 of the second pixel cell is the twice the above length “A2” of the interval (i.e., 2*A2). In the embodiment, the length “A1” and the length “A2” are equal to each other.

In a variation, a dummy member made of e.g., gate electrode material may be provided on a region surrounded by a broken line shown in FIG. 4 or 5.

### (2) Variation

The embodiment described above is mere an example of various embodiments of the present disclosure. The above described embodiment may be modified in various ways in accordance with design or the like as long as the object of the present disclosure can be achieved.

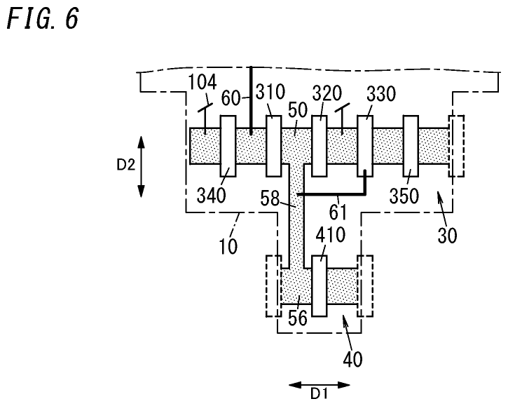

In a solid-state imaging device 1 of one variation, a first diffusion region 50 and a second diffusion region 56 in a pixel cell 10 may be connected by a diffusion layer wiring 58 formed in a semiconductor substrate 100, as shown in FIG. 6. The diffusion layer wiring 58 includes a n-type diffusion region formed in the p-type well region 9. The diffusion layer wiring 58 has a first end connected to the first diffusion region 50 and a second end connected to the second diffusion region 56. Specifically, the first diffusion region 50, the second diffusion region 56, and the diffusion layer wiring 58 may be formed integrally.

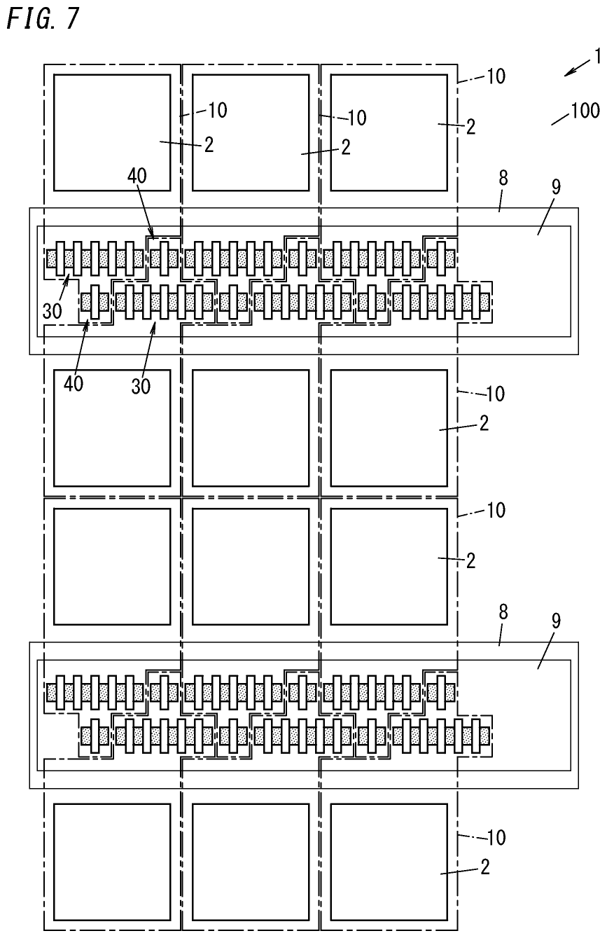

In a solid-state imaging device 1 of one variation, two pixel cells 10 may be arranged to face each other with a p-type well region 9 interposed therebetween such that ends in a first direction D1 of respective light receiving part 2 thereof are on a same line extending in a second direction D2, as shown in FIG. 7. In this case, light receiving parts 2 of a plurality of pixel cells 10 may be arranged in a matrix arrangement.

A pixel cell 10 may include no second reset transistor 34. A pixel cell 10 may include no select transistor 35.

A pixel cell 10 may be configured such that a second diffusion region 56 does not face a first diffusion region 50 in a second direction D2. Such an arrangement where the second diffusion region 56 is apart from a plurality of first transistors 3 in a second direction D2 without facing a first diffusion region 50 can reduce a length of a wiring 61 (or diffusion layer wiring 58) connecting the first diffusion region 50 and the second diffusion region 56, compared to a case where a second transistor 4 is arranged alongside of a plurality of first transistors 3 in a first direction D1.

A controller of a solid-state imaging device 1 may be configured to control pixel cells 10 to operate in a second receiving mode only, without operating in a first receiving mode.

An impurity diffusion region(s) of a first transistor 3 and a second transistor 4 may be p-type conducting properties. For example, the impurity diffusion region(s) of the first transistor 3 and the second transistor 4 may be a p-type diffusion region formed in a n-type well region.

### (3) Summary

It is apparent from the embodiment and variations described above, following aspects are disclosed in the disclosure.

A solid-state imaging device (1) of a first aspect includes a plurality of pixel cells (10) formed in a semiconductor substrate (100) and arranged in a two-dimensional array. At least one pixel cell (10) of the plurality of pixel cells (10) includes a light receiving part (2), a pixel circuit (30), and a second transistor (4). The light receiving part (2) is configured to receive an incident light to generate an electrical charge. The pixel circuit (30) includes a plurality of first transistors (3) arranged side by side along a first direction (D1), and a charge retention part (5). The charge retention part (5) is configured to retain the electrical charge generated by the light receiving part (2). The pixel circuit (30) is configured to output a light receiving signal in accordance with the electrical charge generated by the light receiving part (2). The second transistor (4) connects the charge retention part (5) to a memory part (6) that is configured to store the electrical charge. The pixel cell (10) is configured such that, in plan view seen along a thickness direction of the semiconductor substrate (100), the second transistor (4) is apart from the plurality of first transistors (3) in a second direction (D2) orthogonal to the first direction (D1).

This aspect can reduce the length of a wiring (61) that connects the second transistor (4) to the charge retention part (5), compared to a case where a second transistor (4) is placed alongside of a plurality of first transistors (3) in a first direction (D1). This can reduce the parasitic capacitance of the wiring (61) to achieve high gain for the photoelectric conversion and high sensitivity. This also can reduce the parasitic resistance of the wiring (61) to achieve a high responsiveness for transfer of electrical charge. Furthermore, adjacent pixel cells (10) are arranged such that the first circuit (30) of one and the second circuit (40) of the other are disposed in proximity to each other, which can achieve high integration.

The solid-state imaging device (1) of second aspect is based on the first aspect. In the second aspect, the pixel cell (10) is configured as follows. The charge retention part (5) includes a diffusion region (50) having a floating potential. The plurality of first transistors (3) includes a transfer transistor (31) configured to transfer the electrical charge generated by the light receiving part (2) to the diffusion region (50), a reset transistor (32) configured to reset the electrical charge stored in the diffusion region (50), and an amplifier transistor (33) having a gate electrode (330) electrically connected to the diffusion region (50).

With this aspect, the pixel circuit (30) that includes the transfer transistor (31), the reset transistor (32), and the amplifier transistor (33) can generate the light receiving signal in accordance with the light received by the light receiving part (2).

The solid-state imaging device (1) of a third aspect is based on the second aspect. In the third aspect, the pixel cell (10) is configured as follows. The diffusion region (50) is a first diffusion region (50). The second transistor (4) includes a second diffusion region (56) having a floating potential. The first diffusion region (50) and the second diffusion region (56) are connected to each other. When seen along the second direction (D2), at least part of the first diffusion region (50) and at least part of the second diffusion region (56) overlap each other.

This aspect can reduce the direct distance between the first diffusion region (50) and the second diffusion region (56), leading to reduce the length of the wiring (61) connecting the first diffusion region (50) and the second diffusion region (56) to reduce the parasitic capacitance of the wiring (61).

The solid-state imaging device (1) of a fourth aspect is based on the third aspect. In the fourth aspect, the pixel cell (10) is configured such that, when seen along the second direction (D2), a whole of one of the first diffusion region (50) and the second diffusion region (56) overlaps the other of the first diffusion region (50) and the second diffusion region (56).

With this aspect, a whole length of the side of the one of the first diffusion region (50) and the second diffusion region (56) can be connected to the other thereof. This can increase the width of the wiring connecting the first diffusion region (50) and the second diffusion region (56) to reduce the resistance of the wiring.

The solid-state imaging device (1) of a fifth aspect is based on the third or fourth aspect. In the fifth aspect, the pixel cell (10) is configured such that the first diffusion region (50) and the second diffusion region (56) are connected to each other by a metal wiring (61).

According to this aspect where the first diffusion region (50) and the second diffusion region (56) are connected by the wiring layer, each of the first diffusion region (50) and the second diffusion region (56) may be shaped like a simple rectangle, which enables to reduce the piece-to-piece variation in the characteristics caused by the manufacturing process.

The solid-state imaging device (1) of a sixth aspect is based on the third or fourth aspect. In the sixth aspect, the pixel cell (10) is configured such that the first diffusion region (50) and the second diffusion region (56) are connected to each other by a diffusion layer wiring (58) formed in the semiconductor substrate (100)

According to this aspect where the first diffusion region (50) and the second diffusion region (56) are connected by the diffusion layer wiring (58), the connection part have a reduced parasitic capacitance per length, compared to a case of using the wiring layer for connection.

The solid-state imaging device (1) of a seventh aspect is based on any one of the first to sixth aspects. In the seventh aspect, the pixel cell (10) is configured as follows. The plurality of first transistors (3) have gate electrodes, respectively. The gate electrodes of the plurality of first transistors (3) are arranged side by side along the first direction (D1). The plurality of first transistors (3) includes positioned at both ends in the first direction (D1), and remaining first transistors (3). Gate electrodes of the remaining first transistors (3) are positioned at any of virtual points that equally divides a line segment connecting two gate electrodes of the two first transistors (3) positioned at both ends in the first direction (D1).

With this aspect, the gate electrodes of the plurality of first transistors (3) are positioned at virtual points equally spaced. This can achieve an arrangement where the gate electrodes of the plurality of first transistors (3) are substantially equally spaced, which enables to reduce the piece-to-piece variation in the characteristics caused by the manufacturing process.

The solid-state imaging device (1) of an eighth aspect is based on any one of the first to seventh aspects. In the eighth aspect, the plurality of pixel cells (10) have a same shape as each other in the plan view seen along the thickness direction of the semiconductor substrate (100).

This aspect allows the wirings (60. 61) of the plurality of pixel cells (10) to have the same shape, which can equalize the length of the wirings (60, 61) of the plurality of pixel cells (10) to equalize the parasitic resistance and parasitic capacitance of the wirings (60, 61).

The solid-state imaging device (1) of a ninth aspect is based on any one of the first to eighth aspects. In the ninth aspect, the plurality of pixel cells (10) includes a first pixel cell and a second pixel cell arranged adjacent to each other in the first direction (D1). The plurality of first transistors (3) of the first pixel cell have gate electrodes, respectively. The second transistor (4) of the second pixel cell has a gate electrode. The gate electrodes of the plurality of first transistors (3) of the first pixel cell and the gate electrode of the second transistor (4) of the second pixel cell are arranged side by side along the first direction. The gate electrodes of the plurality of first transistors (3) of the first pixel cell and the gate electrode of the second transistor (4) of the second pixel cell includes two gate electrodes positioned at both ends in the first direction (D1) and gate electrodes of remaining transistors. The gate electrodes of the remaining transistors are positioned at any of virtual points that equally divides a line segment connecting the two gate electrodes of the transistors positioned at both ends in the first direction (D1).

With this aspect, the gate electrodes of the plurality of first transistors (3) of the first pixel cell and the gate electrode of the second transistor (4) of the second pixel cell are positioned at virtual points equally spaced. This can achieve an arrangement where the gate electrodes are substantially equally spaced, which enables to reduce the piece-to-piece variation in the characteristics caused by the manufacturing process.

The solid-state imaging device (1) of a tenth aspect is based on any one of the first to ninth aspects. In the tenth aspect, the plurality of pixel cells (10) includes two pixel cells (10). In the plan view seen along the thickness direction of the semiconductor substrate (100), the light receiving part (2) of one of the two pixel cells (10) is adjacent to the light receiving part (2) of the other of the two pixel cells (10), or the pixel circuit (30) of one of the two pixel cells (10) is adjacent to the pixel circuit (30) of the other of the two pixel cells (10).

This aspect can allow the pixel circuits (30) of the two pixel cells (10) arranged adjacent in the second direction (D2) to be positioned in a common well region, for example. This can allow the well layer to be used in common among a plurality of pixel cells (10) to achieve the high integration, compared to a case where two pixel cells (10) are arranged along a second direction (D2) such that a light receiving part (2) of one of them and a pixel circuit (30) of the other of them are adjacent to each other, for example.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solid-state imaging device, comprising a plurality of pixel cells formed in a semiconductor substrate and arranged in a two-dimensional array,
at least one pixel cell of the plurality of pixel cells including:
a light receiving part configured to receive an incident light to generate an electrical charge;
a pixel circuit that includes a plurality of first transistors arranged side by side along a first direction, and a charge retention part configured to retain the electrical charge generated by the light receiving part, the pixel circuit being configured to output a light receiving signal in accordance with the electrical charge generated by the light receiving part; and
a second transistor connecting the charge retention part to a memory part configured to store the electrical charge, and
the at least one pixel cell is configured such that, in plan view seen along a thickness direction of the semiconductor substrate, the second transistor is apart from the plurality of first transistors in a second direction orthogonal to the first direction.

2. The solid-state imaging device of claim 1, wherein the at least one pixel cell is configured such that:
the charge retention part includes a diffusion region having a floating potential; and
the plurality of first transistors includes
a transfer transistor configured to transfer the electrical charge generated by the light receiving part to the diffusion region,
a reset transistor configured to reset the electrical charge stored in the diffusion region, and
an amplifier transistor having a gate electrode electrically connected to the diffusion region.

3. The solid-state imaging device of claim 2, wherein the at least one pixel cell is configured such that:
the diffusion region is a first diffusion region;
the second transistor includes a second diffusion region having a floating potential;
the first diffusion region and the second diffusion region are connected to each other; and
when seen along the second direction, at least part of the first diffusion region and at least part of the second diffusion region overlap each other.

4. The solid-state imaging device of claim 3, wherein the at least one pixel cell is configured such that, when seen along the second direction, a whole of one of the first diffusion region and the second diffusion region overlaps an other of the first diffusion region and the second diffusion region.

5. The solid-state imaging device of claim 3, wherein the at least one pixel cell is configured such that the first diffusion region and the second diffusion region are connected to each other by a metal wiring.

6. The solid-state imaging device of claim 3, wherein the at least one pixel cell is configured such that the first diffusion region and the second diffusion region are connected to each other by a diffusion layer wiring formed in the semiconductor substrate.

7. The solid-state imaging device of claim 1, wherein the at least one pixel cell is configured such that:
the plurality of first transistors have gate electrodes, respectively, the gate electrodes of the plurality of first transistors being arranged side by side along the first direction,
the plurality of first transistors includes two first transistors positioned at both ends in the first direction and remaining first transistors,
gate electrodes of the remaining first transistors are positioned at any of virtual points that equally divides a line segment, and
the line segment connects two gate electrodes of the two first transistors positioned at both ends in the first direction.

8. The solid-state imaging device of claim 1, wherein, in the plan view seen along the thickness direction of the semiconductor substrate, the plurality of pixel cells have a same shape as each other.

9. The solid-state imaging device of claim 1, wherein
the plurality of pixel cells includes a first pixel cell and a second pixel cell arranged adjacent to each other,
the plurality of first transistors of the first pixel cell have gate electrodes, respectively,
the second transistor of the second pixel cell has a gate electrode,
the gate electrodes of the plurality of first transistors of the first pixel cell and the gate electrode of the second transistor of the second pixel cell are arranged side by side along the first direction,
the gate electrodes of the plurality of first transistors of the first pixel cell and the gate electrode of the second transistor of the second pixel cell includes two gate electrodes of transistors positioned at both ends in the first direction and gate electrodes of remaining transistors,
the gate electrodes of the remaining transistors are positioned at any of virtual points that equally divides a line segment, and
the line segment connects the two gate electrodes of the transistors positioned at both ends in the first direction.

10. The solid-state imaging device of claim 1, wherein the plurality of pixel cells includes two pixel cells adjacent in the second direction,
in the plan view seen along the thickness direction of the semiconductor substrate,
the light receiving part of one of the two pixel cells is adjacent to the light receiving part of an other of the two pixel cells, or
the pixel circuit of one of the two pixel cells is adjacent to the pixel circuit of an other of the two pixel cells.
